(19) United States
(12) Patent Application Publication
(10) Pub. No.: US 2022/0154894 A1
(43) Pub. Date: May 19, 2022

(54) METHOD FOR CREATING LIGHTING EFFECT BY TWO SEGMENTS ON ONE FILAMENT

(71) Applicant: ZHEJIANG TWINSEL ELECTRONIC TECHNOLOGY CO., LTD., NINGBO (CN)

(72) Inventors: Xueren ZENG, NINGBO (CN); Qian XU, NINGBO (CN); Xueyi ZENG, NINGBO (CN); Zhenzhong KONG, NINGBO (CN); Jiawei LI, NINGBO (CN); Rongqu TANG, NINGBO (CN); Xiaofeng TANG, NINGBO (CN)

(73) Assignee: ZHEJIANG TWINSEL ELECTRONIC TECHNOLOGY CO., LTD., NINGBO (CN)

(21) Appl. No.: 17/147,276

(22) Filed: Jan. 12, 2021

(30) Foreign Application Priority Data
Oct. 30, 2020 (CN) 202011185709.5

(51) Int. Cl. F21K 9/64; F21V 23/00; F21S 4/28

(52) U.S. Cl. CPC F21K 9/64; F21Y 2115/10; F21S 4/28; F21V 23/001

(57) ABSTRACT

A method for creating a lighting effect by two segments on one filament, comprising a first fluorescent rubber strip and a second fluorescent rubber strip installed by butting, and a chip support arranged between the first fluorescent rubber strip and the second fluorescent rubber strip; a plurality of LED chips are evenly arranged on the chip support, and the LED chips are in positive and negative parallel connection with each other by conducting wires; and metal wire lugs are installed at both ends of the chip support. Compared with the prior art, the method can be applied to some special application scenarios, such as a light which can illuminate without a drive. By arranging the LED chips in positive and negative inverse parallel connection on the same light-emitting filament, light emitting by two or more segments on one filament or light emitting at intervals is realized, so that non-polar light emitting of the filament is realized.

### TECHNICAL FIELD

The present invention relates to the technical field of LED filaments, and in particular to a method for creating a lighting effect by two segments on one filament.

### BACKGROUND

An LED light source is an energy-saving, green and environment-friendly lighting source. This kind of light source has the advantages such as environmental friendliness, high light efficiency, no radiation and low power consumption, can be used continuously for tens of thousands of hours, and is increasingly popular with consumers in the field of lighting. In recent years, an LED filament lamp light source, which has both the high light efficiency of an LED light source and the form of a tungsten filament lamp, is well received by the market after emergence. At present, the connection mode adopted by filament lamp chips on the market is mostly full series or full parallel connection, which is used to apply to different voltages. However, filaments in the mode of full series or full parallel connection cannot be applied to some special application scenarios, such as a light which can illuminate without a drive, or string lights which require one filament to flash in segments to realize interval light emitting and non-polar light emitting.

### SUMMARY

A technical problem to be solved by the present invention is to provide a method for creating a lighting effect by two segments on one filament aiming at the problems of the prior art.

A technical solution adopted to solve the technical problems by the present invention is as follows:

A method for creating a lighting effect by two segments on one filament, comprising the following steps:

Step 1: installing a first fluorescent rubber strip and a second fluorescent rubber strip by butting, and arranging a chip support between the first fluorescent rubber strip and the second fluorescent rubber strip;

Step 2: evenly arranging a plurality of LED chips on the chip support, wherein the LED chips are evenly distributed along the chip support and are in positive and negative parallel connection with each other by conducting wires; and

Step 3: installing metal wire lugs at both ends of the chip support.

Preferably, the LED chips in step 2 are arranged in positive and negative parallel connection in segments on the chip support.

Preferably, the LED chips in step 2 are arranged in positive and negative parallel connection at intervals on the chip support.

Compared with the prior art, the method for creating a lighting effect by two segments on one filament of the present invention has the following beneficial effects: the method can be applied to some special application scenarios, such as a light which can illuminate without a drive. By arranging the LED chips in positive and negative inverse parallel connection on the same light-emitting filament, light emitting by two or more segments on one filament or light emitting at intervals is realized, so that non-polar light emitting of the filament is realized.

### DESCRIPTION OF DRAWINGS

FIG. 1 is an exploded view of a filament structure of a method for creating a lighting effect by two segments on one filament of the present invention.

FIG. 2 is a structural schematic diagram of a chip support of a method for creating a lighting effect by two segments on one filament of the present invention (with LED chips arranged in positive and negative parallel connection in segments).

FIG. 3 is a partial enlarged view of position A in FIG. 2 of a method for creating a lighting effect by two segments on one filament of the present invention.

FIG. 4 is a structural schematic diagram of a chip support of a method for creating a lighting effect by two segments on one filament of the present invention (with LED chips arranged in positive and negative parallel connection at intervals).

FIG. 5 is a partial enlarged view of position B in FIG. 4 of a method for creating a lighting effect by two segments on one filament of the present invention.

Numerals in the figures: 1. first fluorescent rubber strip; 2. second fluorescent rubber strip; 3. chip support; 31. metal wire lug; 4. LED chip; and 5. conducting wire.

### DETAILED DESCRIPTION

The present invention is further described below in detail in combination with the drawings and embodiments.

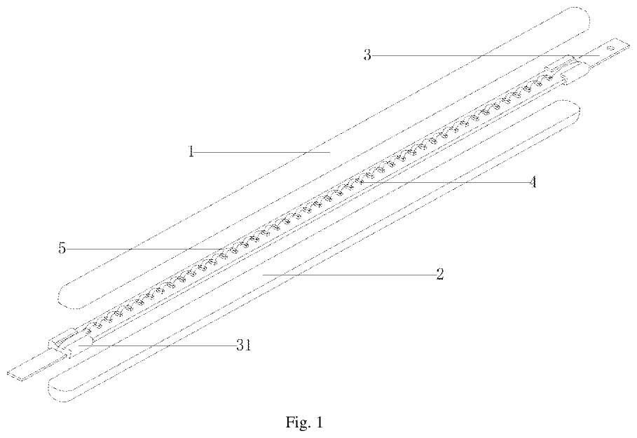

As shown in FIG. 1, a method for creating a lighting effect by two segments on one filament, comprising the following steps:

Installing a first fluorescent rubber strip 1 and a second fluorescent rubber strip 2 by butting, and arranging a chip support 3 between the first fluorescent rubber strip 1 and the second fluorescent rubber strip 2;

Evenly arranging a plurality of LED chips 4 on the chip support 3, wherein the LED chips 4 are evenly distributed along the chip support 3 and are in positive and negative parallel connection with each other by conducting wires 5; and

Installing metal wire lugs 31 at both ends of the chip support 3.

Embodiment 1

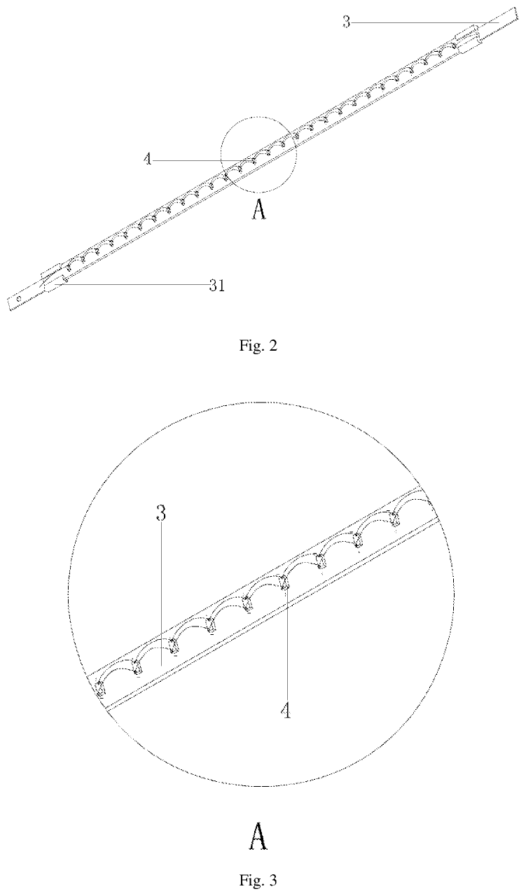

As shown in FIG. 2 to FIG. 3, in this embodiment, the LED chips 4 are arranged in positive and negative parallel connection in segments on the chip support 3, i.e., the LED chips 4 arranged on the left side of the chip support 3 have the positive electrodes on the top and the negative electrodes on the bottom, and the LED chips 4 arranged on the right side have the negative electrodes on the top and the positive electrodes on the bottom; the positive electrodes of the LED chips 4 on the left side are connected to the negative electrodes of the LED chips 4 on the right side in sequence, and the negative electrodes of the LED chips 4 on the left side are connected to the positive electrodes of the LED chips 4 on the right side in sequence.

Embodiment 2

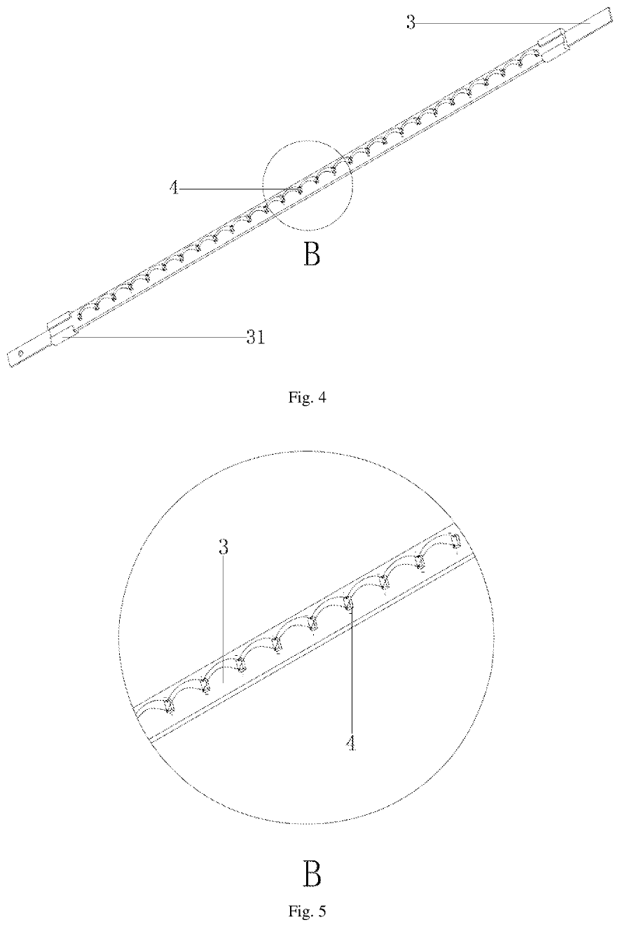

As shown in FIG. 4 to FIG. 5, this embodiment is different from embodiment 1 in that the LED chips 4 are arranged in positive and negative parallel connection at intervals on the chip support 3, i.e., the positive electrodes and the negative electrodes of the LED chips 4 are alternately and evenly distributed, the positive electrode of one LED chip 4 is connected with the negative electrode of an adjacent LED chip 4, and the others are arranged in sequence.

Compared with other ordinary LED chips which require a DC voltage and have a fixed polarity, the LED chips 4 arranged in positive and negative inverse parallel connection can realize light emitting by two or more segments on one filament or light emitting at intervals, so as to realize non-polar light emitting.

The present invention provides a method for creating a lighting effect by two segments on one filament; compared with the prior art, the method can be applied to some special application scenarios, such as a light which can illuminate without a drive. At the same time, by arranging the LED chips in positive and negative inverse parallel connection on the same light-emitting filament, light emitting by two or more segments on one filament or light emitting at intervals is realized, so that non-polar light emitting of the filament is realized.

Finally, it should be noted that the above embodiments are only used for describing the technical solution of the present invention rather than limitation. Although the present invention is described in detail by referring to the above embodiments, those ordinary skilled in the art should understand that: the technical solution recorded in each of the above embodiments can be still amended, or some technical features therein can be replaced equivalently. However, these amendments or replacements do not enable the essence of the corresponding technical solution to depart from the spirit and the scope of the technical solution of various embodiments of the present invention.

1. A method for creating a lighting effect by two segments on one filament, comprising the following steps:
step 1: installing a first fluorescent rubber strip and a second fluorescent rubber strip by butting, and arranging a chip support between the first fluorescent rubber strip and the second fluorescent rubber strip;
step 2: evenly arranging a plurality of LED chips on the chip support, wherein the LED chips are evenly distributed along the chip support and are in positive and negative parallel connection with each other by conducting wires, the LED chips are arranged in positive and negative inverse parallel connection in segments on the chip support, or the LED chips are arranged in positive and negative inverse parallel connection at intervals on the chip support; and
step 3: installing metal wire lugs at both ends of the chip support.

2-3. (canceled)

4. The method of claim 1, wherein the chip support has a first end, a second end opposite to the first end in a longitudinal direction of the chip support, a first side, and a second side opposite to the first side in a width direction of the chip support,
the plurality of LED chips includes a first group of LED chips and a second group of LED chips adjacent to the first group of LED chips in the longitudinal direction,
positive electrodes of the first group of LED chips and negative electrodes of the second group of LED chips are disposed at the first side and connected with each other in sequence,
negative electrodes of the first group of LED chips and positive electrodes of the second group of LED chips are disposed at the second side and connected with each other in sequence.

5. The method of claim 1, wherein the chip support has a first end, a second end opposite to the first end in a longitudinal direction of the chip support, a first side, and a second side opposite to the first side in a width direction of the chip support,
a positive electrode of each LED chip of the plurality of LED chips is disposed at a same side of the chip support as a negative electrode of an adjacent LED chip,
electrodes of the plurality of LED chips at the same side of the chip support are connected with each other in sequence.

6. The method of claim 1, wherein the chip support has a first end, a second end opposite to the first end in a longitudinal direction of the chip support,
the metal wire lugs includes a first metal wire lug and a second metal wire lug,
the first metal wire lug is disposed between the first end of the chip support and the plurality of LED chips,
the second metal wire lug is disposed between the second end of the chip support and the plurality of LED chips.

7. A method for creating a lighting effect by two segments on one filament, comprising the following steps:
step 1: installing a first fluorescent rubber strip and a second fluorescent rubber strip by butting, and arranging a chip support between the first fluorescent rubber strip and the second fluorescent rubber strip;
step 2: evenly arranging a plurality of LED chips on the chip support, wherein the LED chips are evenly distributed along the chip support and are in positive and negative parallel connection with each other by conducting wires, and the LED chips are arranged in positive and negative inverse parallel connection in segments on the chip support; and
step 3: installing a first metal wire lug and a second metal wire lug on the chip support,
wherein the chip support has a first end, a second end opposite to the first end in a longitudinal direction of the chip support, a first side, and a second side opposite to the first side in a width direction of the chip support,
the plurality of LED chips includes a first group of LED chips and a second group of LED chips adjacent to the first group of LED chips in the longitudinal direction,
positive electrodes of the first group of LED chips and negative electrodes of the second group of LED chips are disposed at the first side and connected with each other in sequence, and
negative electrodes of the first group of LED chips and positive electrodes of the second group of LED chips are disposed at the second side and connected with each other in sequence.

8. The method of claim 7, wherein the first metal wire lug is disposed between the first end of the chip support and the plurality of LED chips,
the second metal wire lug is disposed between the second end of the chip support and the plurality of LED chips.

9. A method for creating a lighting effect by two segments on one filament, comprising the following steps:
step 1: installing a first fluorescent rubber strip and a second fluorescent rubber strip by butting, and arranging a chip support between the first fluorescent rubber strip and the second fluorescent rubber strip;
step 2: evenly arranging a plurality of LED chips on the chip support, wherein the LED chips are evenly distributed along the chip support and are in positive and negative parallel connection with each other by conducting wires, and the LED chips are arranged in positive and negative inverse parallel connection at intervals on the chip support; and
step 3: installing a first metal wire lug and a second metal wire lug on the chip support,
wherein the chip support has a first end, a second end opposite to the first end in a longitudinal direction of the chip support, a first side, and a second side opposite to the first side in a width direction of the chip support,
a positive electrode of each LED chip of the plurality of LED chips is disposed at a same side of the chip support as a negative electrode of an adjacent LED chip,
electrodes of the plurality of LED chips at the same side of the chip support are connected with each other in sequence.

10. The method of claim 9, wherein the first metal wire lug is disposed between the first end of the chip support and the plurality of LED chips,
the second metal wire lug is disposed between the second end of the chip support and the plurality of LED chips.
